(19) United States
(12) Patent Application Publication
(10) Pub. No.: US 2013/0270505 A1
(43) Pub. Date: Oct. 17, 2013

(54) MICROELECTRONIC DEVICE WITH PROGRAMMABLE MEMORY, INCLUDING A LAYER OF DOPED CHALCOGENIDE THAT WITHSTANDS HIGH TEMPERATURES

(71) Applicant: ALTIS SEMICONDUCTOR, Corbeil Essonnes (FR)

(72) Inventor: FAIZ DAHMANI, LA VARENNE-SAINT HILAIRE (FR)

(21) Appl. No.: 13/646,882

(22) Filed: Oct. 8, 2012

(30) Foreign Application Priority Data
Oct. 10, 2011 (FR) 11 59124

(51) Int. Cl. H01L 45/00

(52) U.S. Cl. CPC H01L 45/1253; H01L 45/16
USPC 257/4; 438/381

(57) ABSTRACT

A microelectronic device with programmable memory (10) includes a first metallic electrode (2) deposited at least in part on a substrate (1), a doped chalcogenide layer (3) deposited on the first metallic electrode (2) and a second metallic electrode (4) deposited on the doped chalcogenide layer (3). The device further has an intermediate layer (5) positioned between the first metallic electrode (2) and the doped chalcogenide layer (3), the intermediate layer (5) being a layer of a metallic element having the following properties a and b: a) a coefficient of thermal conductivity greater than or equal to 60 W/m·K; and b) mechanical stress less than or equal to −1600 MPa.

### RELATED APPLICATION

This application claims the benefit of priority from French Patent Application No. FR 11 59124, filed on Oct. 10, 2011, the entirety of which is incorporated by reference.

### BACKGROUND

1. Field of the Invention

The present invention relates to a microelectronic device with programmable memory, including a layer of doped chalcogenide that withstands high temperatures, and also to a method of fabricating said device.

2. Description of Prior Art

Microelectronic devices with programmable memory are typically, but not exclusively, programmable cells with ionic conduction (metallization) constituting so-called “non-volatile” computer memory. Such programmable cells having ionic conduction are also known as conductive-bridging random access memory (CBRAM) or programmable metallization cells (PMCs).

This type of microelectronic structure (CBRAM or PMC) is well known to the person skilled in the art, and is described for example in document U.S. Pat. No. 6,084,796.

Typically, a CBRAM (or PMC) comprises a vertical stack of layers made up of a substrate based on a silicon type semiconductor having the following successive layers located thereon forming a three-layer structure: a so-called “bottom” electrode, a layer of a chalcogenide glass doped with silver (i.e. solid electrolyte), and a so-called “top” electrode of silver. The layer of chalcogenide glass (or chalcogenide layer) is thus interposed between the bottom and top electrodes.

Those electrodes are configured to cause a metal dendrite to grow (thereby forming an electrical conduction bridge) from the more negative of the two electrodes towards the more positive of the two electrodes through the layer of doped chalcogenide glass when a voltage is applied to said electrodes. By applying an opposite voltage between those two electrodes, the opposite phenomenon is obtained, i.e. the metal dendrite disappears (i.e. the electrical conduction bridge disappears) from within the layer of doped chalcogenide glass.

Thus, when the electrical conduction bridge is created (a so-called “writing” step) the logic state of the device may be represented by “1”, or may correspond to a “ON” state, whereas when the electrical conduction bridge disappears, the logic state of the cell may be represented by a “0” or may correspond to the “OFF” state.

When the three-layer structure of the CBRAM is made, the stack formed in that way is subjected to steps during which temperature may be relatively high while it is being fabricated.

More particularly, once the active elements such as transistors, etc. have been implanted in steps subsequent to forming the three-layer CBRAM structure, they need to be interconnected in order to form an electrical circuit. Making interconnections of that type is performed at the end of the fabrication line (known as the “back-end-of-line” (BEOL)). At the BEOL, the CBRAM structure may be subjected to temperatures lying in the range 300° C. to 450° C.

A GeS₂ type chalcogenide that is stoichiometric (i.e. a non-doped chalcogenide) is known to have a glass transition temperature that is relatively high, thereby enabling it to remain stable in an amorphous state up to 450° C. without being subjected to any crystallization.

Nevertheless, when the chalcogenide is doped with silver, the presence of silver can lead to a significant drop in its glass transition temperature.

Thus, the temperatures lying in the range 300° C. to 450° C. as the BEOL can cause the physiochemical properties of the silver doped chalcogenide to be degraded.

For example, agglomerations of silver may appear within and around the layer of doped chalcogenide. These agglomerations of silver may lead to short circuits between a plurality of CBRAM cells, and thus to a loss of electrical performance.

If the BEOL temperature exceeds 300° C., it is possible to observe not only undulations appearing within and around the layer of doped chalcogenide (i.e. precursors of possible crystallization), thereby weakening the CBRAM structure to such an extent as to run the risk of breaking it, but also crystallization of the doped chalcogenide, which thus passes from an amorphous state so a crystalline state. The CBRAM then becomes unusable.

### OBJECTS AND SUMMARY

The object of the present invention is to mitigate the drawbacks of the prior art, in particular by proposing a microelectronic device with programmable memory, having a layer of doped chalcogenide, while making it possible to limit significantly or even avoid degradation of said layer at high temperatures, which may in particular be as high as 450° C., or even more.

The present invention provides a microelectronic device with programmable memory, comprising:

a first metallic electrode deposited at least in part on a substrate;

a doped chalcogenide layer deposited on the first metallic electrode; and

a second metallic electrode deposited on the doped chalcogenide layer;

the device being characterized in that it further comprises an intermediate layer positioned between the first metallic electrode and the doped chalcogenide layer, said intermediate layer being a layer of a metallic element having the following properties a and b:

a. a coefficient of thermal conductivity greater than or equal to 60 watts per meter per kelvin (W/m·K or Wm⁻¹K⁻¹), preferably greater than or equal to 70 W/m·K, preferably greater than or equal to 90 W/m·K, and more preferably greater than or equal to 100 W/m·K; and

b. mechanical stress less than or equal to −1600 megapascals (MPa), and preferably less than or equal to −2000 MPa.

The term “layer of a metallic element” is used to mean a layer including at least said metallic element, preferably a layer comprising essentially said metallic element, and in more particularly preferred manner a layer comprising only said metallic element in the substantially pure state.

When the layer comprises only said metallic element, it should be considered that it comprises “substantially” only one metallic element. The term “substantially” means that the intermediate layer may include inevitable impurities in addition to said metallic element. By way of example, the intermediate layer may comprise at least 98% by weight of said metallic element and preferably at least 99% by weight of said metallic element, with the remainder of the intermediate layer being constituted by inevitable impurities.

The term “inevitable impurities” covers all metallic or non-metallic elements included in the intermediate layer during fabrication of the metallic element. By way of example, these impurities may be one or more of the following elements: Ag, Cd, Cr, Fe, Mg, Mn, Pb, S, Si, Ti, V, Ni, S, Fe, and/or Zn.

In the present invention, the coefficient of thermal conductivity of a metallic element is well known to the person skilled in the art, and in particular this value is specific to each element and can be obtained from the periodic table of elements.

Mechanical stress is determined at ambient temperature (i.e. 25° C.) using an instrument of the Flexus type (Tencor).

The instrument measures the radius of curvature of the substrate (before and after depositing the intermediate layer) by interferometry using a laser beam. Mechanical stress values are then calculated directly using Stoney's formula, given that the thickness of the intermediate layer and of the substrate, and their respective Young's moduluses and Poisson coefficients are known.

The mechanical stress expressed in the present invention has a negative value, i.e. it corresponds to so-called “compressive” stress. When the value of the mechanical stress is positive, then it is conventional to refer to “tensile” stress.

The Applicant has discovered, surprisingly, that by interposing an intermediate layer of a metallic element having said properties a and b, between the first metallic electrode (“bottom” electrode) and the doped chalcogenide layer, the chalcogenide layer is much better at withstanding the high temperatures required for the BEOL steps that are subsequent to depositing the second electrode (“top” electrode).

More particularly, the intermediate layer serves to limit significantly or even to avoid degradation of the chalcogenide layer at high temperatures, which temperatures may be as high as 450° C. or even higher. Thus, at the BEOL, the temperatures applied do not run any significant risk of damaging the microelectronic device with programmable memory.

In addition, the intermediate layer of the invention may also act as a diffusion barrier. It can thus serve to prevent the dopant element(s) (from the doped chalcogenide layer) from diffusing into the first electrode. As a result, because of this diffusion barrier, the electrical efficiency of the microelectronic device of the invention, and thus its electrical performance, are optimized.

The metallic element of the intermediate layer may be a transition metal. The metallic element of the intermediate layer is preferably ruthenium (Ru). Ruthenium presents a coefficient of thermal conductivity of about 117 W/m·K (property a), and a mechanical stress of about −2600 MPa.

The thickness of the intermediate layer may lie in the range 3 nanometers (nm) to 7 nm, and may preferably be equal to 5 nm.

In a particular embodiment of the invention, the microelectronic device need not include an intermediate layer (with the properties a and b as defined in the present invention) positioned between the doped chalcogenide layer and the second metallic electrode.

Preferably, the microelectronic device of the invention may include, as an intermediate layer as defined in the invention, only the intermediate layer that is positioned between the first metallic electrode and the doped chalcogenide layer.

If an intermediate layer were to be positioned between the doped chalcogenide layer and the second electrode, that intermediate layer would act as a diffusion barrier, thereby preventing an electrical conduction bridge being formed within the doped chalcogenide when a voltage is applied between the first and second electrodes.

The doped chalcogenide layer is conventionally in electrical contact with the first and second electrodes in order to be capable of forming electrical conduction bridges when a voltage is applied between those two electrodes. Consequently, since the intermediate layer is a layer of a metallic element, and thus an electrically conductive layer, electrical contact between the chalcogenide layer and the first electrode is maintained.

In a particular embodiment, the intermediate layer is directly in physical contact with the first metallic electrode and with the doped chalcogenide layer.

In the present invention, the term “substrate” designates any type of structure, such as semiconductor substrates in particular, that may conventionally be based on silicon and/or on quartz. By way of example, the semiconductor substrate may be selected from substrates of silicon, silicon oxide, and quartz.

By way of example, the semiconductor substrate may comprise silicon-on-insulator (SOI) or silicon-on-sapphire (SOS) type semiconductors, doped or non-doped semiconductors, and/or layers of silicon grown epitaxially on a semiconductor base. Steps of the method may be used to form regions or junctions in or above the semiconductor base.

The substrate is not necessarily semiconductive, but may be any type of support structure suitable for supporting an integrated circuit. For example, the substrate may be made of ceramic or it may be based on polymer.

By way of example, the substrate may have thickness lying in the range 150 micrometers (μm) to 400 μm, or possibly extending up to 800 μm.

The first and second electrodes of the invention correspond respectively to an anode or a cathode, or vice versa.

The first electrode (i.e. “bottom” electrode) may be defined as being an inert electrode. The to “inert” is used of an electrode to designate an electrode that does not contribute to forming the electrical conduction bridge. In other words, the material of the first electrode is different from the material constituting the metallic element doping the layer of doped chalcogenide material.

The first electrode may typically be made of a material selected from nickel, tungsten, a nickel alloy, a tungsten alloy, titanium, titanium nitride, tantalum, tantalum nitride, and a mixture thereof.

The second electrode (i.e. “top” electrode) may be defined as being a reactive electrode: said second electrode is preferably different from the first electrode. The term “reactive” is used of an electrode to designate an electrode that participates in forming the electrical conduction bridge. In other words, the material of the second electrode is different from the material constituting the metallic element doping the layer of doped chalcogenide material.

The metal of the second metallic electrode is preferably identical to the metallic doping element used for doping the (previously non-doped) chalcogenide layer. In other words, the second electrode may be identical to the material of the ionizable metallic layer.

The second electrode may typically be made of a material selected from silver (Ag), a silver alloy, copper (Cu), a copper alloy, zinc (Zn), a zinc alloy, and a mixture thereof. The particularly preferred material being silver or a silver alloy.

By way of example, the first and second electrodes may have thickness lying in the range 100 nm to 300 nm for the first electrode and in the range 10 nm to 100 nm for the second electrode.

In the invention, the material of the chalcogenide layer is constituted in particular by an amorphous material.

It comprises a chalcogenide, which is preferably a chalcogenide glass.

A chalcogenide is conventionally made up of at least one chalcogen ion and at least one electropositive element.

The chalcogens that constitute chalcogen ions are located in group 16 (i.e. group VIA) of the periodic table of elements, and those that are preferably used in the invention are sulfur (S), selenium (Se), and tellurium (Te).

The electropositive element constituting the chalcogenide may, more particularly, be:

an element of group 14 (i.e. group IVA) of the periodic table of elements, such as in particular silicon (Si) or germanium (Ge); or

an element of group 15 (i.e. group VA) of the periodic table of elements, such as in particular phosphorus (P), arsenic (As), antimony (Sb), or bismuth (Bi).

Said electropositive element is preferably germanium (Ge) or arsenic (As).

The term chalcogenide glass is used typically when the electropositive element of the chalcogenide belongs to group 14 or to group 15 of the periodic table of elements.

As examples of chalcogenides, mention may be made of germanium selenide GeₓSe₁₀₀₋ₓ, germanium sulfide GeₓS₁₀₀₋ₓ, or arsenic sulfide AsₓS₁₀₀₋ₓ, where x is an integer, in particular lying in the range 1 to 99, and preferably in the range 18 to 50.

The preferred chalcogenide is germanium sulfide GeₓS₁₀₀₋ₓ, in particular with 33≦x≦44, and in more particularly preferred manner with x=33.

By way of example, the thickness of the chalcogenide layer may lie in the range 15 nm to 100 nm, and preferably lies in the range 20 nm to 50 nm.

The layer of doped chalcogenide includes at least one dopant element of the metallic element type.

This metallic element may preferably be selected from silver (Ag), a silver alloy, copper (Cu), a copper alloy, zinc (Zn), a zinc alloy, or a mixture thereof, the particularly preferred element being silver or a silver alloy.

In the invention, the layer of doped chalcogenide is more particularly an amorphous layer.

In a preferred embodiment, the microelectronic device of the invention is a programmable cell with ionic conduction (CBRAM or PMC).

As a result, the microelectronic device of the invention cannot be considered as being a phase-change material (PCM) in which the chalcogenide changes phase by going from an amorphous state to a crystalline state.

More particularly, the first and second electrodes are configured to cause a metallic dendrite to grow (i.e. to form an electrical conduction bridge) from the more negative of the two electrodes towards the more positive of the two electrodes through the layer of doped chalcogenide when a voltage is applied between said electrodes. When applying an opposite voltage between those two electrodes, the phenomenon inverses, i.e. the metallic dendrite disappears (i.e. the electrical conduction bridge disappears) within the layer of doped chalcocenide.

The invention also provides the method of fabricating a microelectronic device with programmable memory, as defined above, the method being characterized in that it comprises the following steps:

i. depositing a first metallic electrode on a substrate;

ii. depositing an intermediate layer of a metallic element having properties a and b on the first electrode;

iii. depositing a chalcogenide layer on the intermediate layer;

iv. depositing an ionizable metallic layer on the chalcogenide layer;

v. diffusing metallic ions from the ionizable metallic layer of step iv in the chalcogenide layer in order to form the doped chalcogenide layer; and

vi. depositing a second metallic electrode on the doped chalcogenide layer.

In a particular implementation, step ii is performed by direct current (DC) or radiofrequency (RF) cathode sputtering.

By way of example, when the metallic element that is to be deposited is ruthenium, step ii is performed by DC cathode sputtering under argon at a pressure of 0.2 millitorr (mTorr) to 1 mTorr and at a power density of 1.3 watts per square centimeter (W/cm²) to 2 W/cm².

Steps i, iii, iv, v, and vi are steps well known to the person skilled in the art.

A few non-limiting implementations of each of these steps are mentioned below.

The first and second electrodes of the invention are in particular metallic electrodes deposited by a chemical technique (chemical vapor deposition (CVD)) or by cathode sputtering (physical vapor deposition (PVD)) for the first electrode, and by RF or DC cathode sputtering for the second electrode.

In order to obtain a layer of doped chalcogenide, it is possible to begin by depositing a layer of non-doped chalcogenide by cathode sputtering, and then to deposit on said layer of chalcogenide a metallic layer that is ionizable by cathode sputtering.

Thus, a layer of doped chalcogenide is formed by applying a diffusion step that serves to cause metallic ions from the ionizable metallic layer to diffuse through the chalcogenide layer.

This diffusion step may be performed by irradiation using ultraviolet rays and/or heat treatment, where both these two types of diffusion are well known to the person skilled in the art.

In a first variant, step iv that consists in depositing a second metallic electrode on the layer of doped chalcogenide may be an additional step after step iv.

In a second variant, step iv that consists in depositing a second metallic electrode on the layer of doped chalcogenide may be included in step iv. In other words, step iii serves both to deposit an ionizable metallic layer on the layer of chalcogenide, and also to deposit the second electrode while there still remains a portion of the ionizable metallic layer that has not been diffused (consumed) during diffusion step v.

The method of the invention may also include a heat treatment step vii, subsequent to step vi, consisting in heating the microelectronic device to a temperature higher than or equal to the glass transition temperature of the layer of doped chalcogenide.

By way of example, heat treatment is performed at a temperature of at least 300° C.

Thus, because of the intermediate layer of the invention, the layer of doped chalcogenide is substantially not degraded.

The invention also provides the use of a metallic element having above-defined properties a and b in a microelectronic device with programmable memory, including a layer of doped chalcogenide.

This use may serve to limit significantly or even avoid degradation of the layer of doped chalcogenide at high temperatures, which temperatures may possibly be as high as 450° C., or even higher.

### BRIEF DESCRIPTION OF THE DRAWINGS

Other characteristics and advantages of the present invention appear in the light of the following examples given with reference to the annotated figures, which examples and figures are given by way of non-limiting illustration.

FIG. 1 is a fragmentary cross-section view of a stack of layers of a microelectronic device with programmable memory of the invention.

FIG. 2 is a flow chart showing the method of fabricating the FIG. 1 microelectronic device.

FIGS. 3a and 3b are scanning electron microscope (SEM) images of a stack of layers of the prior art, before and after heat treatment at 300° C. for 10 minutes.

FIG. 4 shows optical microscope images of stacks of the prior art and of the invention, after heat treatment at 350° C. for 15 minutes.

FIG. 5 shows scanning electron microscope (SEM) images of a stack of the invention after heat treatment at 450° C. for 15 minutes.

### DETAILED DESCRIPTION

For reasons of clarity, only elements that are essential for understanding the invention are shown, and they are shown diagrammatically without necessarily being to scale.

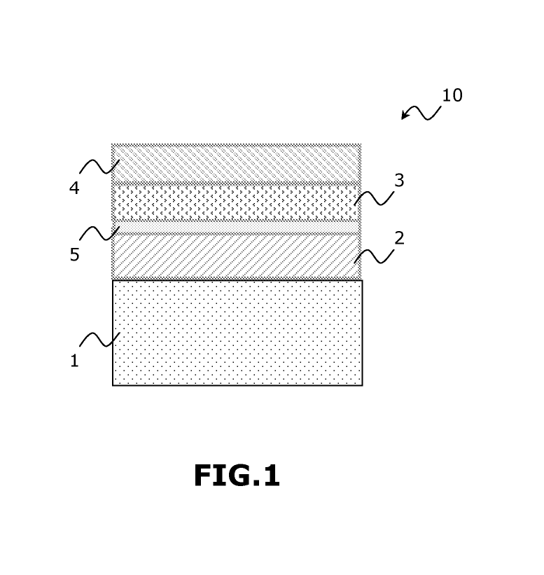

FIG. 1 shows a particular stack 10 forming a microelectronic device with programmable memory, in accordance with the invention.

Said stack 10 comprises the following successive layers:

a substrate 1 comprising at least one layer placed on silicon and optionally a succession of elements well known to the person skilled in the art, the thickness of the substrate being of the order of 300 micrometers (μm);

a layer 2 of tungsten forming the first electrode (i.e. the “bottom” electrode), the thickness of this layer being about 300 nm;

an intermediate layer 5 of ruthenium, the thickness of this layer being about 5 nm;

a layer 3 of a chalcogenide glass of the GeS₂ type, doped with silver, the thickness of this layer being about 50 nm; and
a layer 4 of silver forming the second electrode (i.e. the “top” electrode), the thickness of this layer being about 30 nm.

Naturally, the microelectronic device with programmable memory of the invention may include other layers deposited on the second electrode.

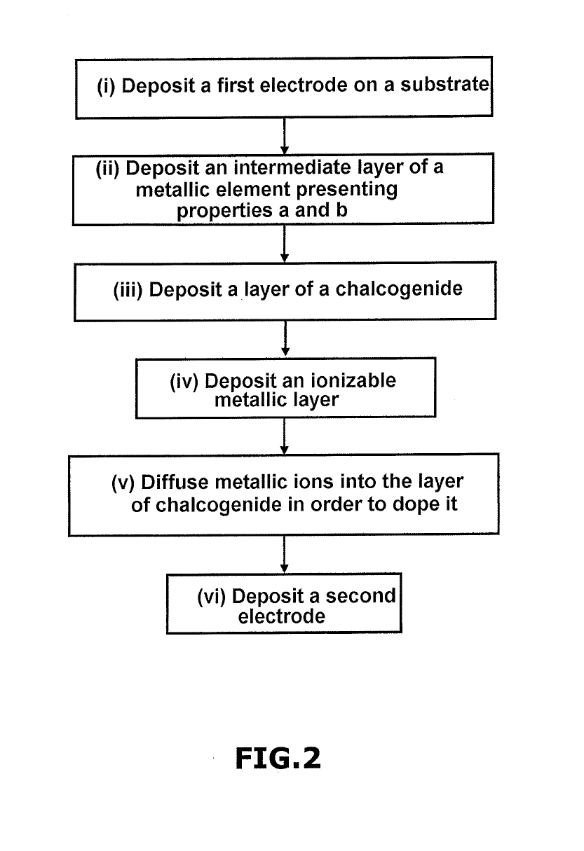

The stack of FIG. 1 was made using the method steps shown in detail in the flow chart of FIG. 2.

In a first step (step i), the tungsten electrode 2 is deposited on the silicon based substrate 1 by chemical vapor deposition (CVD).

Thereafter, in a second step (step ii), the ruthenium layer 5 is deposited on the tungsten electrode 2 by cathode sputtering with a power density of 1.5 W/cm² in an argon atmosphere at a pressure of 0.4 mTorr.

Thereafter, in a third step (step iii), a layer of non-doped GeS₂ type chalcogenide glass is deposited on the ruthenium layer, by cathode sputtering.

In a fourth step (step iv), a 20 nm thick layer of silver (or silver alloy) is then deposited on the non-doped GeS₂ type chalcogenide glass layer by vacuum cathode sputtering in an argon atmosphere.

In a fifth step (step v), this silver layer is then irradiated by ultraviolet radiation at sufficient intensity and for a sufficient duration to ensure that the silver ions coming from the silver layer diffuse into the chalcogenide layer, to form the doped chalcogenide layer 3.

Finally, in a sixth step (step vi), the electrode 4 of silver or silver alloy is deposited on the doped chalcogenide layer by cathode sputtering in a vacuum plasma reactor in the presence of argon.

### EXAMPLES

A series of tests were performed by simulating the heat budget encountered during industrial fabrication of a CBRAM stack by vacuum annealing for 15 minutes at temperatures lying in the range 300° C. to 450° C.

The CBRAM stacks made were of the type shown in FIG. 1, with a few differences, namely:

a stack E1 identical to that of FIG. 1, except that it did not have an intermediate layer of ruthenium;

a stack E2 identical to that of FIG. 1, except that the intermediate layer of ruthenium (Ru) was replaced by a layer of tantalum (Ta);

a stack E3 identical to that of FIG. 1, except that the intermediate layer of ruthenium (Ru) was replaced by a layer of tantalum nitride (TaN);

a stack E4 identical to that of FIG. 1, except that the intermediate layer of ruthenium (Ru) was replaced by a layer of platinum (Pt); and

a stack E5 identical to that of FIG. 1, in accordance with the invention.

The operating conditions for depositing the layers constituting the stacks were identical to those described for FIG. 2, the intermediate layer having a thickness of 5 nm in the stacks E2 to E5.

The thermal conductivity coefficients and the mechanical stresses of the various 5 nm thick intermediate metal layers (Ti, Ta, TaN, Pt, and Ru) are summarized in Table 1 below.

TABLE 1

| | Mechanical stress | Coefficient of |
|---|---|---|
| Intermediate | at 25° C. | thermal conductivity |
| layer | (MPa) | (W/m · K) |
| Ti | −2600 | 21.9 |
| Ta | −1600 | 57.5 |
| TaN | −3700 | <57.5 |
| Pt | +400 | 71.6 |
| Ru | −2600 | 117 |

The respective thermal conductivity coefficients of the elements Ti, Ta, Pt, and Ru are taken from the periodic table of elements.

The thermal conductivity coefficient of TaN depends both on the element Ta and on the element N, and also on their respective atomic weighting in TaN (conventionally 15 atomic percentage (at %) to 20 at % of N in TaN). Since the thermal conductivity coefficient of nitrogen is 0.026 (W/m·K), i.e. much less than the thermal conductivity coefficient of Ta (cf. 57.5 W/m·K), the thermal conductivity coefficient of TaN is therefore less than 57.5 W/m·k (being about 30 W/m·K to 40 W/m·K).

It may be observed that tungsten (K), i.e. the metal used for fabricating the first electrode (the “bottom” electrode) in the example of FIG. 1 has mechanical stress at 25° C. of +20 MPa and a coefficient of thermal conductivity of 174 W/m·K. Its mechanical stress is thus much greater than that of the present invention (property b).

The CBRAM stacks E1 to E5 as formed in that way were placed in a low temperature vertical oven (≦600° C.) of the SVG VTR7000 type in the presence of nitrogen gas and they were subjected for 15 minutes to a temperature lying in the range 300° C. to 450° C.

The surface of each stack as heat treated in that way was inspected optically using an optical microscope of the Leica INS1000i type and/or a scanning electron microscope (SEM).

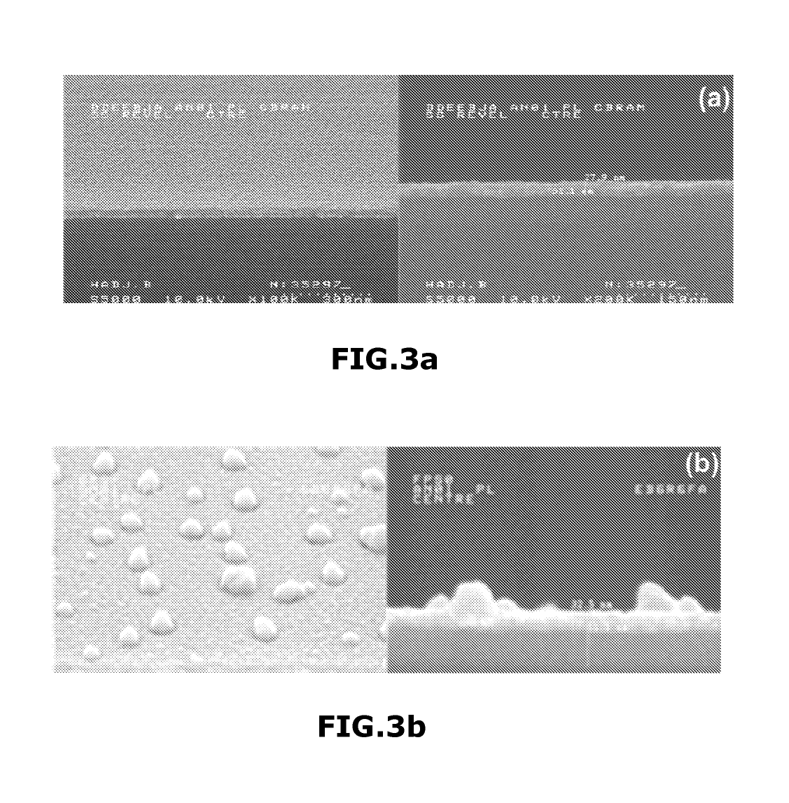

FIGS. 3a and 3b show scanning electron microscope (SEM) images of the stack E1 in semi-inclined view (on the left-hand side) and in cross-section view (on the right-hand side).

FIG. 3a shows the stack E1 without heat treatment.

FIG. 3b shows the stack E1 after heat treatment at 300° C. for 10 minutes. It can clearly be seen that agglomerates of silver have appeared on the surface in FIG. 3b.

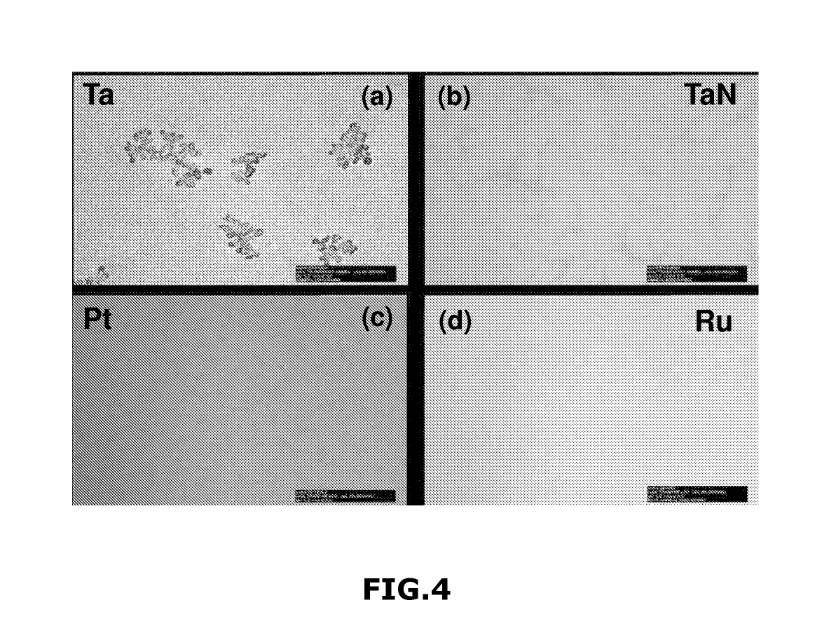

FIG. 4 shows optical microscope images of the stacks E2 (FIG. 4a), E3 (FIG. 4b), E4 (FIG. 4c), and E5 (FIG. 4d), after heat treatment at 350° C. for 15 minutes.

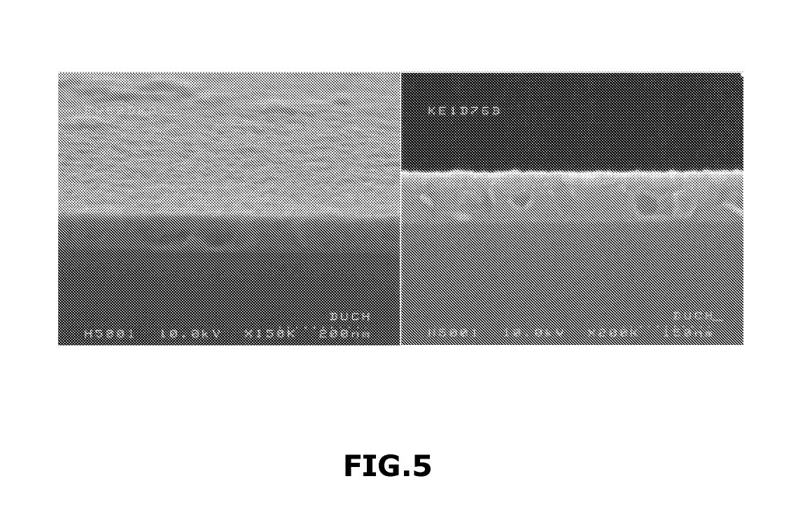

FIG. 5 shows scanning electron microscope (SEM) images of the stack E5 after heat treatment at 450° C. for 15 minutes.

It can be seen very clearly in FIG. 4 that after heat treatment at 350° C. for 15 minutes, the stack E2 with an intermediate layer of tantalum (Ta) presents advanced crystallization, and the stack E3 with an intermediate layer of tantalum nitride (TaN) presents the beginning of silver defects (extrusions). The same observation applies to the intermediate layer of platinum (Pt) (i.e. stack E4) as for the intermediate layer of tantalum nitride (i.e. stack E3), with defects that are less apparent.

The stack E5 does not present any visible defect (e.g. no silver defect and no crystallization), both after heat treatment at 350° C. for 15 minutes (see FIG. 4d) and after heat treatment at 450° C. for 15 minutes (see FIG. 5).

1. A microelectronic device with programmable memory, comprising:
a first metallic electrode deposited at least in part on a substrate;
a doped chalcogenide layer deposited on the first metallic electrode; and
a second metallic electrode deposited on the doped chalcogenide layer;
Wherein said device further comprises an intermediate layer positioned between the first metallic electrode and the doped chalcogenide layer, said intermediate layer being a layer of a metallic element having the following properties a and b:
a. a coefficient of thermal conductivity greater than or equal to 60 W/m·K; and
b. mechanical stress less than or equal to −1600 MPa.

2. A device according to claim 1, wherein the metallic element of the intermediate layer is ruthenium (Ru).

3. A device according to claim 1, wherein the thickness of the intermediate layer lies in the range 3 nm to 7 nm.

4. A device according to claim 1, wherein the intermediate layer is directly in physical contact with the first metallic electrode and with the doped chalcogenide layer.

5. A device according to claim 1, wherein the intermediate layer is a diffusion barrier.

6. A device according to claim 1, wherein the microelectronic device does not include an intermediate layer positioned between the doped chalcogenide layer and the second metallic electrode.

7. A device according to claim 1, wherein said device is a programmable cell with ionic conduction.

8. A method of fabricating a microelectronic device having the structure according to claim 1, said method comprising the steps of:
i. depositing a first metallic electrode on a substrate;
ii. depositing an intermediate layer of a metallic element having properties a and b on the first electrode;
iii. depositing a chalcogenide layer on the intermediate layer;
iv. depositing an ionizable metallic layer on the chalcogenide layer;
v. diffusing metallic ions from the ionizable metallic layer of step iv in the chalcogenide layer in order to form the doped chalcogenide layer; and
vi. depositing a second metallic electrode on the doped chalcogenide layer.

9. A method according to claim 8, wherein the intermediate layer is deposited by cathode sputtering.

10. A method according to claim 8, wherein said method includes a heat treatment step vii, subsequent to step vi, including heating the microelectronic device to a temperature greater than or equal to the glass transition temperature of the doped chalcogenide layer.

11. A method according to claim 8, said method further comprising the step of employing a metallic element having properties a and b in a microelectronic device with programmable memory, including a layer of doped chalcogenide.
